(19) United States
(12) Patent Application Publication
(10) Pub. No.: US 2009/0033327 A1
(43) Pub. Date: Feb. 5, 2009

(54) Magnetic Resonance Imaging of a Continuously Moving Object

(75) Inventors: Bernd Aldefeld, Hamburg (DE); Peter Boernert, Hamburg (DE); Jochen Keupp, Hamburg (DE)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N. V., Eindhoven (NL)

(21) Appl. No.: 11/911,723

(22) PCT Filed: Apr. 7, 2006
(86) PCT No.: PCT/IB2006/051076

§ 371 Date: Oct. 17, 2007

(30) Foreign Application Priority Data
Apr. 18, 2005 (EP) 05103041.9

(51) Int. Cl. G01R 33/563

(52) U.S. Cl. 324/309

(57) ABSTRACT

A continuous moving table magnetic resonance imaging method is proposed where a ‘lateral’ read out is performed that is transverse to the direction of motion. This magnetic resonance imaging method for imaging a moving object includes spatially selective RF excitations are applied for respective phase-encodings. The sub-volume is excited by the spatially selective RF excitation moves with the motion of the object for respective subsets of primary phase-encodings. Acquisition of magnetic resonance signals is performed from a three-dimensional sub-volume of the object. The magnetic resonance signals are read encoded in a direction transverse to the direction of motion of the object and phase-encoded in at least the direction of motion of the object.

The invention pertains to a magnetic resonance imaging method of a continuously moving object. There is a general need of magnetic resonance imaging of a object that is larger than the available field of view of the magnetic resonance imaging system. Further, imaging of a continuously moving object is considered more attractive than moving the object in steps to a number of stations and concatenate the images acquired at the individual stations to form the image of the object.

A magnetic resonance imaging method of the type that is generally termed ‘continuously moving table imaging’ is known from the US-patent application US 2004/0155654.

The known magnetic resonance imaging method uses continuous table motion along the z-axes, while acquiring magnetic resonance signals. From the magnetic resonance signals there are reconstructed magnetic resonance images across a large effective field of view. At each position of the table full z-spatial encoding data are acquired. These full z-data are Fourier transformed in the z-direction, interpolated, sorted and aligned to match anatomic z-locations. From the data that are aligned along the z-direction a final image of the object is reconstructed.

An object of the invention is to provide a magnetic resonance imaging method of the ‘continuously moving table’ type that is more efficient than the already known moving-table MR methods.

This object is achieved according to the invention by the magnetic resonance imaging method for imaging a moving object including
spatially selective RF excitations are applied for respective phase-encodings and the sub-volume being excited by the spatially selective RF excitation moves with the motion of the object for respective subsets of primary phase-encodings,
acquisition of magnetic resonance signals from a three-dimensional sub-volume of the object,
the magnetic resonance signals being
   read encoded in a direction transverse to the direction of motion of the object and
   phase-encoded in at least the direction of motion of the object.

According to the invention the excited sub-volume moves with the object to be examined, e.g. a patient to be examined, for a specific sub-set of the phase encoding steps. In particular the sub-volume moves from an initial to a final position and periodically returns to the initial position for a subsequent sub-set of phase encoding steps (this process may be indicated as ‘slab jitter’). The sub-volume in which by way of RF-excitations a transverse magnetisation is generated is spatially displaced from one phase-encoding step to the next. Because the excited sub-volume moves with the same speed as the object, during this sub-set of phase encoding steps magnetic resonance signals are acquired from essentially the same portion of the object. The sub-set typically comprises a full set of phase encodings in the motion direction z (secondary phase encoding) in order to acquire a consistent dataset for one phase encoding step in the transverse (y) direction (primary phase encoding). This is distinct from known slab tracking methods, where the RF excitations continuously moves with the patient during all y and z encoding steps. Nevertheless, according to the invention, any number of y encoding steps for one slab motion period can be implemented. Further, according to the invention, frequency encoding (or readout) is applied in a lateral direction that is transverse, e.g. orthogonal to the direction of motion of the object. Further phase-encoding is applied in that a primary phase-encoding is applied transverse to the direction of motion and transverse, e.g. orthogonal, to the frequency encoding direction. For genuine volume encoding of a three-dimensional sub-volume a secondary phase-encoding is applied along the direction of motion. Alternatively, the excited sub-volume may be a two-dimensional slice that moves with the object from one primary phase-encoding to the next in the slice. It is noted, however, that acquisition of magnetic resonance signals from a three-dimensional volume with two independent phase-encodings yields a better signal-to-noise ration than acquisition of magnetic resonance signals from a two-dimensional slice with phase-encoding in only one direction in that slice. The acquisition of magnetic resonance signals according to the invention is more efficient because the frequency encoding in the lateral direction provides full coverage of the entire width of the object, while artefacts are avoided notably due to system imperfections, notably inhomogeneities of the main magnetic field. Thus, the magnetic resonance imaging method of the invention is both more efficient in acquisition of magnetic resonance signals and less prone to artefacts in the magnetic resonance image. The frequency encoding in the lateral direction allows coverage of the patient's body over its full width (e.g. shoulder-to-shoulder) without fold-over artefacts. Notably, a time consuming high sampling density phase-encoding in the lateral dimension is avoided. Further, additional alignment of the acquired magnetic resonance signals, e.g. on a line-by-line basis in k-space to account for motion of the object is easily implemented.

Further, because frequency-encoding is applied in the lateral direction, transverse to the direction of motion, a very high sampling density of the magnetic resonance signals in k-space is achieved without a substantial increase of scan time to acquire the magnetic resonance signals. Upon reconstruction this allows very high spatial resolution along orientations transverse to the direction of blood vessels, so that very thin blood vessels can be resolved.

The magnetic resonance imaging method of the invention is also generally applicable and highly flexible in that is compatible with many types of acquisition sequences, in particular with radial and spiral acquisition trajectories in k-space.

It is noted that applying the frequency encoding along the lateral direction is mentioned per se in the conference proceedings ‘Extending the coverage of true volume scans by continuous movement of the subject’ by O. Dietrich and J. V. Hajnal in Proc. ISMRM 7(1999)1653. That approach is only effective in that it allows scanning over regions of space that are much longer than supported by limitations in magnet homogeneity. However, the combination with a variable slab jitter or slab tracking, according to the invention, enables the full range of applications with respect to table speed and other scanning parameters. Owing to slab tracking, phase encodings in motion direction are kept consistent and less prone to artefacts.

These and other aspects of the invention will be further elaborated with reference to the embodiments defined in the dependent Claims.

According to a further aspect of the invention the frequency encoding is applied along the largest dimension of the object transverse to the direction of motion. In clinical practice the frequency encoding is applied in the patient's left-right direction, while the patient is moved along the longitudinal, head-feet direction. Thus, the most time-efficient spatial (i.e. frequency-)encoding is applied along the largest lateral dimension, which relatively reduces the scan time to acquire the magnetic resonance signals for individual sets of phase- and frequency encoded magnetic resonance signals of the sub-volume at issue.

The sub-volume has the shape of a rectangular slab in the transversal plane which has a larger extension in the lateral direction than in the longitudinal direction of motion. In this way adverse effects in moving table imaging due to spatial non-uniformities of the gradient fields and the static magnetic field are avoided. Because the primary and secondary phase-encodings are applied along directions where the sub-volume has a relative small size, the phase-encoding directions can be sampled efficiently.

Further, because the size of the sub-volume is relatively small along the direction of motion, artefacts in the magnetic resonance image are avoided, notably because the sub-volume remains comfortably within the region where there is accurate homogeneity of the main magnetic field B₀ and there is accurate control of the RF-excitation field B₁. In other words, the smaller the size of the sub-volume in the direction of motion, the more effective areas of B₀ and/or B₁ inhomogeneities are avoided when acquiring magnetic resonance signals.

According to another aspect of the invention the size of the sub-volume is set in dependence of the distance the sub-volume travels in the time needed to acquire magnetic resonance signals for a preset number of phase-encodings. The preset number may be derived from a full sampling density in k-space that is related to a preset spatial resolution of the magnetic resonance image. The preset number may alternatively be derived from a preset undersampled sampling density in k-space. When such undersampling in the phase-encoding directions in k-space is applied, the magnetic resonance image needs to be reconstructed on the basis of spatial sensitivity profiles of the receiver antennae (receiver coils) by which the magnetic resonance signals are received. This approach of undersampling in k-space and employing the spatial sensitivity profiles is generally indicated as parallel imaging. Because the size of the sub-volume is set in dependence of the distance traveled during acquisition of the preset number of phase-encodings, good control of the spatial coverage of the imaging of the moving object is achieved. Especially, when the size of the sub-volume along the direction of motion equals the distance over which the sub-volume travels during the preset number of phase-encodings, accurate fitting of subsequent sets of phase-encoded magnetic resonance signals for the moving sub-volume are obtained. If the travel distance is short, the sub-volume can be made large, without leaving the homogeneity zone of the main magnetic field.

According to a further aspect of the invention the sub volume of frequency (RF) excitation (slab) is moved while the phase encodings are applied. From one phase-encoding to the next the object moves. In order to generate magnetic resonance signals from the same portion of the object, i.e. of the anatomy of the patient to be examined, the sub-volume that is excited is moved from one phase-encoding to the next. More particularly for individual primary phase-encodings the sub-volume is moved from the initial position to subsequent positions for respective secondary phase-encodings. After a predefined number of primary phase-encodings the sub-volume is set to the initial position again until the preset number of phase-encodings is obtained. Then the process is repeated in a periodic repetition for the next initial position of the sub-volume. In this way a type of ‘slab jitter’ is carried out so as to have the RF excited sub-volume move with the object. If the predefined number of primary phase-encodings comprises one full k-space passage, the process merges into what is known as ‘slab tracking’.

According to another aspect of the invention an oversampling in the secondary phase-encoding direction is applied. This oversampling is effected in that a sub-volume in the form of a spatial slab which is RF excited and encoded is thicker than is needed for image formation. In reconstruction the oversampled data are either discarded or used for data averaging. Consequently, artefacts due to imperfections of the spatial distribution of the RF excitation of the sub-volume (slab) are eliminated.

When no oversampling is applied, the scan time required for acquisition of the magnetic resonance signals is independent of the extension of the field of view in the direction of motion, because a smaller field of view requires a proportionately smaller number of secondary phase encoding steps. When oversampling is applied, some increase in scan time occurs as the field of view is made smaller.

As a further aspect of the invention, a phase correction is applied to the magnetic resonance signals on a line-by-line basis in k-space. That is, e.g. for individual secondary phase encodings the phase of the magnetic resonance signals is corrected to account for motion of the object. Thus, magnetic resonance signals that are obtained from the same portion of the object are also properly spatially encoded within the reference frame of the object. The phase correction may be performed by multiplying the signal value of the magnetic resonance signals by the appropriate phase factor. Alternatively, the phase correction can be done during reception of the magnetic resonance signals by adapting the phase of the receiver.

As a further aspect of the invention, correction of the encoding for movement of the object for the distance the sub-volume travels for successive sets of the preset number of primary phase-encodings is made. The data represented by the magnetic resonance signals are reconstructed into data samples in hybrid space. This hybrid space has two dimensions in k-space and one dimension in the geometrical space of the object. To the data lines reconstructed in this hybrid space a shift in direction of motion is applied.

It is noted that the present invention is applicable to different MR acquisition strategies, such as samplings schemes that are Cartesian in k-space, but also to acquisition schemes which are e.g. radial or spiral in k-space.

The invention also relates to a magnetic resonance imaging system that is arranged to perform the various aspects of the invention. Notably the magnetic resonance imaging system of the invention is provided with a control unit that functions to operate the magnetic resonance imaging system according to the method of the invention. The invention also relates to a computer programme that comprises instructions to perform the various aspects of the invention. Notably the computer programme of the invention can be provided on a data carrier such as a CD-ROM or can be downloaded from a data network such as the world-wide web. The computer programme of the invention is installed in the computer that is usually included in the control unit of the magnetic resonance imaging system. The computer with the computer programme of the invention functions to control the various functions of the magnetic resonance imaging system.

These and other aspects of the invention will be elucidated with reference to the embodiments described hereinafter and with reference to the accompanying drawing wherein

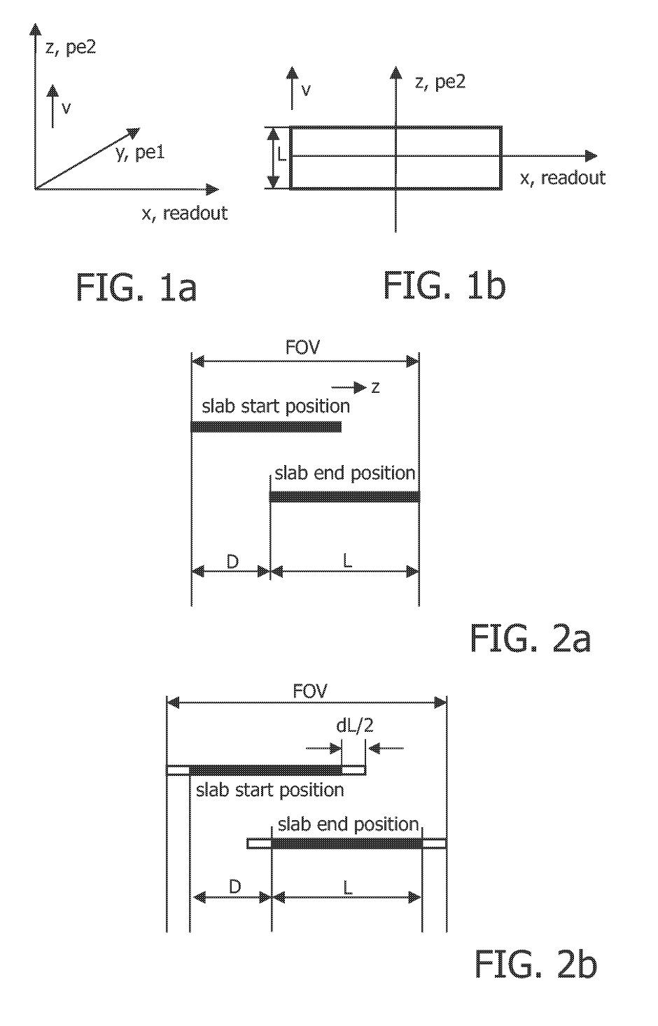

FIG. 1 shows the geometry assumed for a 3D moving table imaging sequence. The frequency-encoding gradient (readout gradient) is oriented perpendicular to the direction of motion. The secondary phase-encoding gradient is parallel to the direction of motion. K-space data are acquired from a slab of length L;

FIG. 2 illustrates the slab sweeping method, (a) basic method, no oversampling used, (b) with oversampling used. Data acquired from the region within the slab (length L, shown as dark region in the figure) is used for reconstruction. Additional regions at the borders of the slab (e.g. of length dL/2) are sampled to improve image quality. D is the distance over which the slab is tracked;

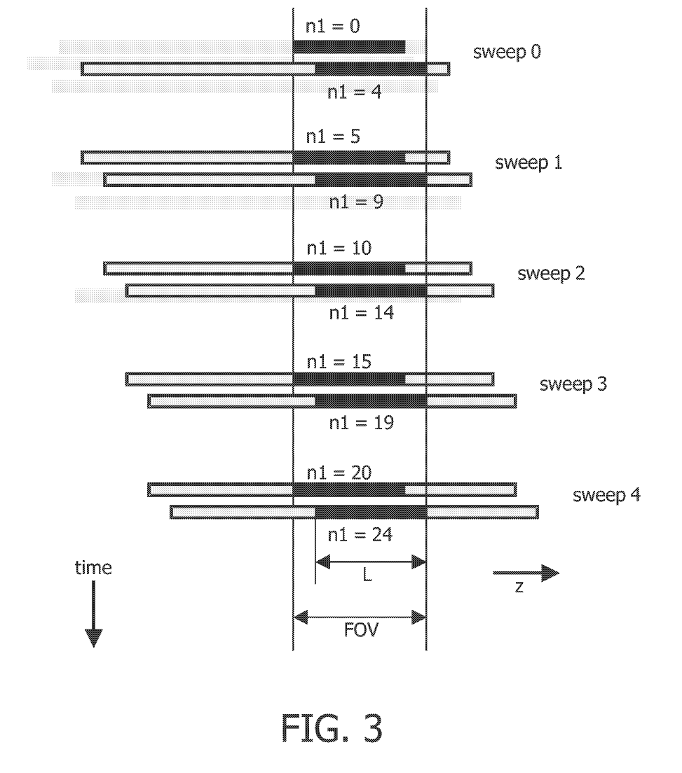

FIG. 3 shows an example of the slab sweeping method; here, one k-space scan is made up of 25 primary phase encodings (indicated by n1=0 to n1=24). Five primary phase encodings are applied during each sweep, for example, n1=0 to 4 in sweep number 0. For each primary phase encoding, all secondary phase encodings are applied (not shown in the figure). After completion of five sweeps, the examination objects has moved the distance L, and the next k-space scan begins;

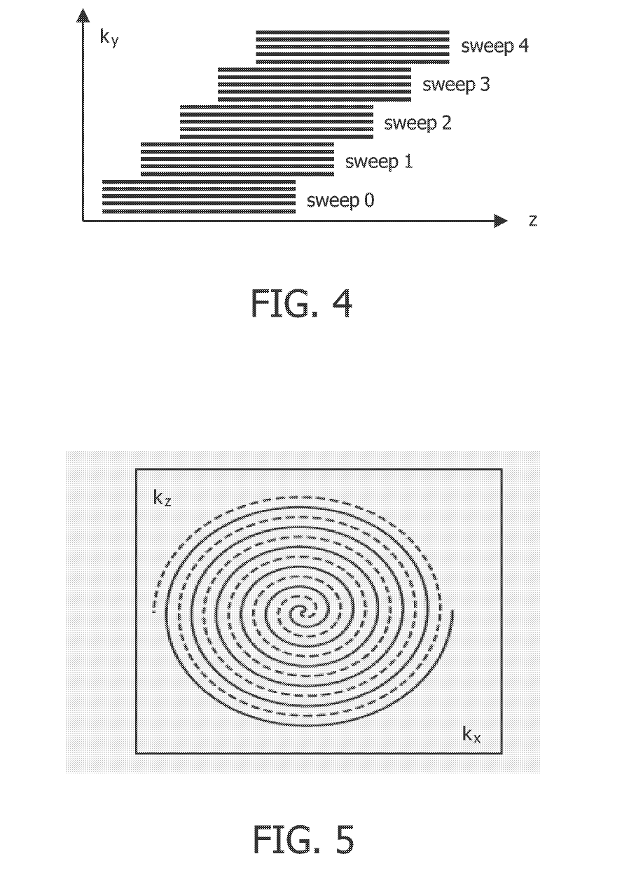

FIG. 4 illustrates an example of data in hybrid space (k_{y},z). The third dimension is either x or kₓ (not shown here). Each line represents data acquired for one primary phase-encoding step. Five primary phase-encoding steps are applied per sweep, and five sweeps complete one k-space scan. Data acquired during a single sweep are positioned at the same z location in hybrid space because their relative positions have already been corrected using Eq. (5). Data for the next k-space scan (not shown here) would align to the right-hand side of data from sweep 0;

FIG. 5 shows an example of interleaved spiral trajectories and

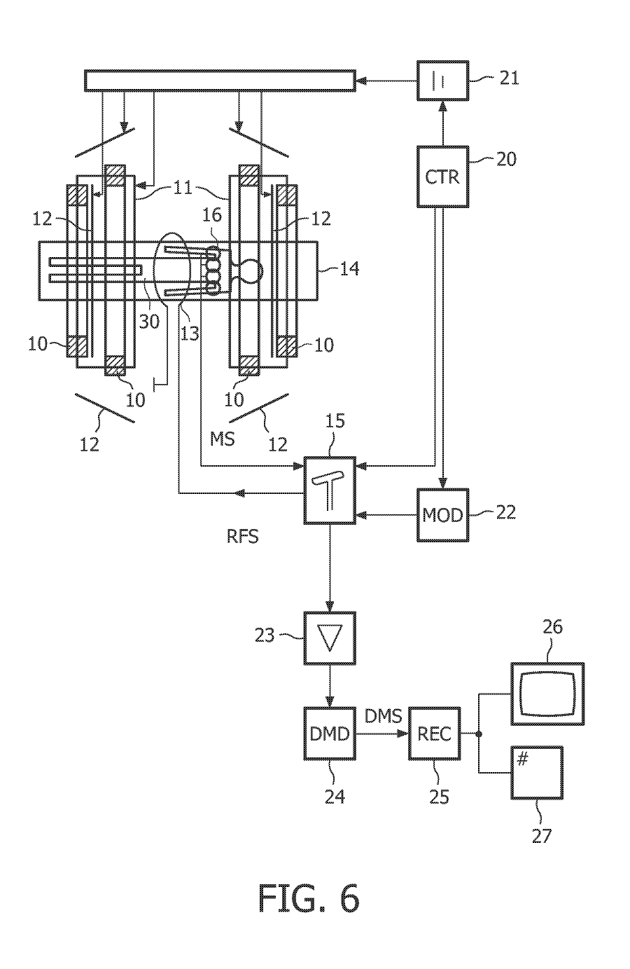

FIG. 6 shows diagrammatically a magnetic resonance imaging system in which the invention is used;

In the following, the invention is described for the case of a three-dimensional MR sequence in which k-space is sampled line by line (Cartesian sampling scheme, e.g. gradient-echo sequence). However, the method is not restricted to this type of sampling schemes. Referring to FIG. 1, x denotes the horizontal (right/left or RL) direction, y the vertical (anterior/posterior or AP) direction, and z the longitudinal (superior/inferior or SI) direction. The direction of motion is assumed along the z direction. The frequency-encoding direction is oriented along x, and the primary and secondary phase-encode directions, pe1 and pe2, are oriented along y and z, respectively. Alternatively, the directions of frequency encoding and first phase encoding can be interchanged. The number of primary and secondary phase encodings used to fully cover k-space are denoted N1 and N2, respectively.

Image acquisition: A slice selective RF pulse is applied to select a slab with thickness L along the z direction. A different slab location is selected for each phase-encoding step such that the slab moves with the same speed and in the same direction as the object. The location of the selected slab varies from a start to an end position as illustrated in FIG. 2a. The distance traveled by the slab between its extreme positions is denoted D. The slab start position is displaced by dz=−D/2 relative to a position centered in the field of view (which usually coincides with the isocenter of the magnet), and the slab end position is displaced by dz=+D/2. During the time when the slab travels from dz=−D/2 to dz=+D/2 (which will be termed a sweep), a subset ΔN1 of all the N1 primary phase encodings are applied, while the full set of N2 secondary phase encodings is applied for each primary phase encoding. The order in which the combination of primary and secondary phase encodings are applied during a sweep is arbitrary. The MR data acquired during one sweep are stored in an intermediate storage device for further processing. The slab position is then reset to dz=−D/2, and the next set of combinations from ΔN1 primary and N2 secondary phase encodings is applied. When all primary and secondary phase encodings have been applied, k-space has been scanned once. The cycle is repeated until all k-space data for the total object to be imaged has been acquired.

The relationship between the slab thickness L, table velocity v, repetition time TR, and number of phase encodings N1 and N2 are chosen such that one set of k-space data is acquired for each part of the object to be imaged. This is accomplished by choosing the relevant parameters according to the equation

L=v·TR·N1·N2 (1)

The slab travel distance is chosen according to

D=v·TR·ΔN1·N2 (2)

The last equation can be transformed using the first one to give

D=L·ΔN1/N1 (3)

The length of the field of view along z in which data are acquired then is

FOVz=L+D (4)

Here, FOVz denotes the length in z direction of the region where signal is acquired. FOVz may be smaller than the extension of the field of view normally used in MR imaging, e.g. to avoid image degradation caused by non-ideal field conditions (gradient non-linearity, main field inhomogeneity, RF coil non-uniformity).

Image reconstruction: The process can be viewed as consisting of two alternating steps that are applied repeatedly. In the first step, acquired lines of k-space are corrected for the phase error caused by the slab motion between its start and end position. The central position in the FOV (e.g. the isocenter) or any other position may be used as the reference position. The correction is done by multiplying the k-space samples in each k-space line by exp(−i·Δφ), where i=\sqrt{−1} and

Δφ=k_{z}·dz (5)

where k_{z} denotes the k-space value applied when the slab has the displacement dz relative to the isocenter. After the slab has completed one sweep, ΔN1 planes of k-space that are spanned by the frequency-encoding and secondary phase-encode directions have been corrected for table motion. In the second step, the k-space planes thus corrected are Fourier transformed in the z direction and stored in a (kₓ, k_{y}, z) data structure (hybrid space). A shift in z direction is applied to compensate for the motion of the planes belonging to one single sweep relative to the scan time elapsed so far. The z location in hybrid space for the data of one single sweep are given by

zₘ=v·tₘ+z₀ (6)

where tₘ denotes the time when the acquisition of sweep number m is started and z₀ is a arbitrary constant. Here a constant table velocity is assumed, however speed variation is possible while the corresponding corrections have to be accepted. After all data have been acquired for the entire object, the remaining Fourier transforms are applied, after which the three-dimensional image representation of the object is obtained.

The correction for the phase error Δφ could alternatively be done during the data acquisition process by adapting the phase of the receiver in real-time. Fourier transformation in the frequency-encoding (x) direction can be done either at the start, during or at the end of the reconstruction process. If done at the start, the hybrid space is spanned by (x, k_{y}, z), but the essence of the method is not changed.

Improvement of the method: The selection of a slab by the RF pulse is not ideal in practice. For example, some signal excitation normally occurs also outside the chosen slab, which results in some external intensity being overlaid onto the desired slab intensity. To prevent this effect, or at least to reduce it to small degree, oversampling is applied in the z direction. To that end, the phase encodings in z direction are increased by ΔN2, so that data from a region with z extension larger than L is acquired. Let δ denote the voxel size in z direction, then dL=ΔN2·δ is the additional length over which data is acquired. In the reconstruction process these additional data are either discarded or used for data averaging. This improves the image quality and also gives some improvement of SNR due to the increase of the sampling time. The additional length may be added symmetrically with respect to the start and end of the chosen slab, i.e. dL/2 is added to the start and dL/2 to the end of the chosen slab as shown in FIG. 2b, but symmetry is not mandatory. Moreover, because the RF profile does not in practice decrease to zero like a step function at the slab borders, the length of the RF-excited region can be extended along z, so that it is longer than the chosen slab thickness. The additional excitation length can be chosen equal to the oversampling length dL, but other choices are possible depending on the characteristics of the RF profile. An additional benefit of enlarging the RF-excited thickness is that the spin system is given some time to establish a steady state transverse magnetization (at least to some degree) when these spins enter the region from which data are used in the reconstruction.

When oversampling in z direction is included, the above equations 1, 2 and 4 are modified and take the following form:

L=v·TR·N1·(N2+ΔN2) (7)

D=v·TR·ΔN1·(N2+ΔN2) (8)

FOVz=L+D+dL (9)

Equation 3 remains unchanged. The only modification of the MR sequence as compared with the basic method is that a thicker slab is encoded by the imaging experiment and/or excited by the RF pulse. In the reconstruction, the oversampled data are discarded. This is done by cutting the additional ΔN2 sampled off after the Fourier transformation in z direction. Alternatively the oversampled data are used for averaging.

Example: As an example of a 3D imaging sequence with Cartesian k-space sampling, assume the following parameters:

| L | 200 mm |
|---|---|
| v | 10 mm/s |
| N1 | 25 |
| ΔN1 | 5 |
| N2 | 100 |
| ΔN2 | 10 |

According to Eq. (7), a repetition time TR=7.27 ms is chosen. The distance D over which the slab is moved during each sweep is obtained from Eq. (3) as D=40 mm. At the start of each sweep, slab selection is displaced in the z direction by −D/2=−20 mm. With each TR, slab selection is shifted by v·TR. FIG. 3 illustrates the slab sweeping. The oversampled region is omitted here for simplicity. After ΔN1=5 primary phase encodings (e.g. n=0 . . . 4 in FIG. 3), each one followed by N2+ΔN2=110 secondary phase encodings, slab selection has traveled D=v·TR·ΔN1·(N2+ΔN2), which is equal to 40 mm. The field of view in which data are acquired has extension L+D=240 mm along z. After phase correction according to Eq. (5), the data acquired in this sweep are Fourier transformed in the z direction and then stored in hybrid space. Data for one single sweep are stored in hybrid space at the same z location, as is illustrated in FIG. 4, because the motion correction of data in one sweep relative to each other has already been effected by the phase correction according to Eq. (5). The z location in hybrid space for the data of one single sweep are given by Eq. (6). After N1/ΔN1=5 sweeps (sweeps 0 . . . 4 in FIGS. 3 and 4), k-space has been scanned once. Data acquisition is then repeated in this manner over several k-space scans depending on the length in z direction of the examination object. After all MR data have been acquired, the remaining Fourier transformations are applied to the hybrid-space data to obtain the image of the examination object.

As another example, consider the set of parameters above but with N1=50 and ΔN1=1. The distance D traveled by the slab in one sweep is then only 4 mm, and the field of view in which data is acquired has extension L+D=204 mm along z, which is only slightly larger than the slab thickness. This choice of parameters allows an especially efficient use of the field of view because MR data are acquired in a region as large as possible.

Further modifications: In the basic method described above, a simple, basic MR sequence was assumed in which the pulse waveforms are the same in each segment of duration TR and in which k-space is scanned in a linear fashion along the phase-encoding directions (e.g. a gradient-echo sequence). The following modifications may be useful:

The number of k-space scans acquired per length L of the object need not be an integer number. Additional k-space data may be acquired and used, for example, for the averaging of data to suppress boundary artefacts or to compensate for variations of the table velocity.

The sampling density (distance between points in k-space) need not be constant. A variable density where the centre of k-space is sampled more densely along the motion direction may be applied, which helps to reduce signal contributions from spins excited outside the chosen slab. The effectiveness of the slab selection along the motion direction is critical because signal from outside the slab is overlaid on the desired signal and may produce artefacts or intensity modulations in the reconstructed image. If the central region of k-space is sampled more densely, then the field of view is enlarged for the low spatial frequencies, where most of the signal energy is concentrated. In the given context, sampling more densely along the z direction can reduce aliased intensity, while only a few additional phase-encoding steps are required.

The order in which phase encodings are acquired need not be linear. (In a linear acquisition, each k-space direction is scanned from minimum to maximum or vice versa, e.g. from k_{y,min} to k_{y,max} and from k_{z,min} to k_{z,max}.) Other phase-encoding orders are important in practice, e.g. to manipulate contrast. For example, assuming that the primary phase encodings are indexed i=0, 1, . . . , N1, then an even-odd acquisition order may be chosen, in which first the phase encodings i=0, 2, . . . , N1−2 and then those with i=1, 3, . . . N1−1 are acquired. The method described in this invention is compatible with any acquisition order since no assumptions have been made in this respect. The only restriction is that complete sets of k_{z} encoded data are required at the end of each sweep.

The basic MR sequence can be modified by addition of preparation pulses applied at constant or varying time intervals. The only modification required to include this feature is a minor change in the timing of the gradient and RF pulses.

The method is not restricted to MR methods in which k-space is scanned line by line as considered above but may be applied also, with suitable modifications, to other k-space scanning schemes such as EPI (echo-planar imaging), spiral or radial schemes. For example, consider a spiral MR scheme. Here k-space is scanned by a spiral trajectory or by a set of interleaved spiral trajectories, as illustrated in FIG. 5 for the case of two interleaves per k-space coverage. For three-dimensional imaging, spiral trajectories may be applied in one plane whereas phase encoding may be applied in the third dimension as in Cartesian sampling schemes (so-called stack of spirals imaging). The spirals may be distorted to better fit a rectangular field of view. In a preferred embodiment, the spirals are oriented in a plane that includes the z direction, e.g. the x-z plane, and the phase encoding is oriented along y. Assuming that Nₛ spiral interleaves are needed to completely cover the k-space plane kₓ-k_{z}, then the moving-table imaging proceeds as follows: For every ΔN1 phase-encoding steps in y direction, spiral interleaves are successively played out while the slab position is advanced with each interleaf by the amount dz=v·TR. After ΔN1 phase encodings, each followed by Nₛ spiral interleaves, the slab end position is reached, and the cycle is repeated. The MR signal from each spiral interleaf is phase corrected according to the current slab position using an extension of Eq. (5), i.e. Δφ(t)=k_{z}(t)·dz(t). Each set of Ns spiral interleaves is reconstructed in the x-z plane and then stored in hybrid space (x,z,k_{y}) at its motion-corrected z location. In a similar way, the moving-table method is applicable to echo-planar imaging (EPI). The process is analogous the spiral case described above, with spiral interleaves replaced by interleaved EPI segments. Also, the method is applicable to radial imaging, with spiral interleaves replaced by sets of radial lines. Another way would be the “stack of stars” or “stack of spirals” acquisition where the remaining phase encoding direction is aligned to the direction of table motion (z).

Corrections with respect to non-ideal magnetic fields can be included. For example, the effects of the non-linearity of the gradient fields can be corrected. Such corrections for non-linearities in the gradient fields are known per se from the U.S. Pat. No. 6,707,300.

FIG. 6 shows diagrammatically a magnetic resonance imaging system in which the invention is used. The magnetic resonance imaging system includes a set of main coils 10 whereby the steady, uniform magnetic field is generated. The main coils are constructed, for example in such a manner that they enclose a tunnel-shaped examination space. The patient to be examined is placed on a patient carrier which is slid into this tunnel-shaped examination space. The magnetic resonance imaging system also includes a number of gradient coils 11, 12 whereby magnetic fields exhibiting spatial variations, notably in the form of temporary gradients in individual directions, are generated so as to be superposed on the uniform magnetic field. The gradient coils 11, 12 are connected to a controllable power supply unit 21. the gradient coils 11, 12 are energised by application of an electric current by means of the power supply unit 21; to this end the power supply unit is fitted with electronic gradient amplification circuit that applies the electric current to the gradient coils so as to generate gradient pulses (also termed ‘gradient waveforms’) of appropriate temporal shape The strength, direction and duration of the gradients are controlled by control of the power supply unit. The magnetic resonance imaging system also includes transmission and receiving coils 13, 16 for generating the RF excitation pulses and for picking up the magnetic resonance signals, respectively. The transmission coil 13 is preferably constructed as a body coil 13 whereby (a part of) the object to be examined can be enclosed. The body coil is usually arranged in the magnetic resonance imaging system in such a manner that the patient 30 to be examined is enclosed by the body coil 13 when he or she is arranged in the magnetic resonance imaging system. The body coil 13 acts as a transmission antenna for the transmission of the RF excitation pulses and RF refocusing pulses. Preferably, the body coil 13 involves a spatially uniform intensity distribution of the transmitted RF pulses (RFS). The same coil or antenna is usually used alternately as the transmission coil and the receiving coil. Furthermore, the transmission and receiving coil is usually shaped as a coil, notably a solenoid. Other geometries of a transmission and receiving antenna for RF electromagnetic signals are also feasible. The transmission and receiving coil 13 is connected to an electronic transmission and receiving circuit 15.

It is to be noted that it is alternatively possible to use separate receiving and/or transmission coils 16. For example, surface coils 16 can be used as receiving and/or transmission coils. Such surface coils have a high sensitivity in a comparatively small volume. The receiving coils, such as the surface coils, are connected to a demodulator 24 and the received magnetic resonance signals (MS) are demodulated by means of the demodulator 24. The demodulated magnetic resonance signals (DMS) are applied to a reconstruction unit. Each receiving coil is connected to a preamplifier 23. The preamplifier 23 amplifies the RF resonance signal (MS) received by the receiving coil 16 and the amplified RF resonance signal is applied to a demodulator 24. The demodulator 24 demodulates the amplified RF resonance signal. The demodulated resonance signal contains the actual information concerning the local spin densities in the part of the object to be imaged. Furthermore, the transmission and receiving circuit 15 is connected to a modulator 22. The modulator 22 and the transmission and receiving circuit 15 activate the transmission coil 13 so as to transmit the RF excitation and refocusing pulses. The reconstruction unit derives one or more image signals from the demodulated magnetic resonance signals (DMS), which image signals represent the image information of the imaged part of the object to be examined. The reconstruction unit 25 in practice is constructed preferably as a digital image processing unit 25 which is programmed so as to derive from the demodulated magnetic resonance signals the image signals which represent the image information of the part of the object to be imaged. The signal on the output of the reconstruction monitor 26, so that the monitor can display the magnetic resonance image. It is alternatively possible to store the signal from the reconstruction unit 25 in a buffer unit 27 while awaiting further processing.

The magnetic resonance imaging system according to the invention is also provided with a control unit 20, for example in the form of a computer which includes a (micro)processor. The control unit 20 controls the execution of the RF excitations and the application of the temporary gradient fields. To this end, the computer program according to the invention is loaded, for example, into the control unit 20 and the reconstruction unit 25.

1. A magnetic resonance imaging method for imaging a moving object including
spatially selective RF excitations are applied for respective phase-encodings and the sub-volume being excited by the spatially selective RF excitation moves with the motion of the object for respective subsets of primary phase-encodings,
acquisition of magnetic resonance signals from a three-dimensional sub-volume of the object,
the magnetic resonance signals being
read encoded in a direction transverse to the direction of motion of the object and
phase-encoded in at least the direction of motion of the object.

2. A magnetic resonance imaging method as claimed in claim 1, wherein the read encoding direction is along the lateral direction that corresponds to the largest dimension of the sub-volume transverse to the direction of motion of the object.

3. A magnetic resonance imaging method as claimed in claim 1, wherein the size of the sub-volume along the lateral direction is larger than the size of the sub-volume along the direction of motion of the object.

4. A magnetic resonance imaging method as claimed in claim 1, wherein
a preset number of phase-encodings is applied to the sub-volume corresponding to a predetermined sampling density in k-space of the magnetic resonance signals from the sub-volume and
the size of the sub-volume is set in dependence of the distance the sub-volume moves during the acquisition time of the preset number of phase-encodings, in particular the dimension of the sub-volume along the direction of motion equals the distance the sub-volume travels during the acquisition time of the preset number of phase-encodings.

5. A magnetic resonance imaging method as claimed in claim 4, wherein the acquisition is performed in periodic repetition of
successive sets of primary phase-encodings and repeated secondary phase-encodings for respective primary phase-encodings and
the distance over which the excited sub-volume is moved equals the distance the table travels during an individual set of primary phase-encodings.

6. A magnetic resonance imaging method as claimed in claim 4 wherein an oversampling in the secondary phase-encoding direction is applied in that the dimension of the RF excited sub-volume along the direction of motion is larger than the distance the sub-volume travels during the acquisition time of the preset number of phase-encodings.

7. A magnetic resonance imaging method as claimed in claim 5, wherein
for individual primary phase-encodings there are applied successive secondary phase-encodings and
the RF excited sub-volume is moved to successive locations for respective secondary phase-encodings.

8. A magnetic resonance imaging method as claimed in claim 1, wherein the phases of magnetic resonance signals of individual lines in k-space are corrected along the k_{z}-direction corresponding to the direction of motion in order to generate phase-corrected magnetic resonance signals for a set of secondary phase-encodings.

9. A magnetic resonance imaging method as claimed in claim 1, wherein
phase-corrected magnetic resonance signals are reconstructed into data samples for respective data lines in a hybrid (k_{⊥},z) space and
shifted data samples are generated by translating the data samples along the direction of motion in accordance with the distance traveled by the moving object for respective sets of primary phase-encodings.

10. A magnetic resonance imaging method as claimed in claim 1, wherein the magnetic resonance signals are acquired by way of a radial or spiral encoding trajectory in k-space.

11. A magnetic resonance imaging system being arranged to
apply selective RF excitations for respective phase-encodings and the sub-volume being excited by the spatially selective RF excitation moves with the motion of the object for respective phase-encodings,
acquire magnetic resonance signals from a three-dimensional sub-volume of the object,
the magnetic resonance signals being
read encoded in a direction transverse to the direction of motion of the object and
phase-encoded in at least the direction of motion of the object.

12. A computer programme comprising instructions to
apply selective RF excitations for respective phase-encodings and the sub-volume being excited by the spatially selective RF excitation moves with the motion of the object for respective phase-encodings,
acquire of magnetic resonance signals from a three-dimensional sub-volume of the object,
the magnetic resonance signals being
read encoded in a direction transverse to the direction of motion of the object and
phase-encoded in at least the direction of motion of the object.

13. A computer programme, in particular as claimed in claim 12, comprising instructions to access magnetic resonance signals being
read encoded in a direction transverse to the direction of motion of the object and
phase-encoded in at least the direction of motion of the object and
correct the phases of magnetic resonance signals of individual lines in k-space along the k_{z}-direction corresponding to the direction of motion in order to generate phase-corrected magnetic resonance signals for a set of secondary phase-encodings and
phase-corrected magnetic resonance signals are reconstructed into data samples for respective data lines in a hybrid (k_{⊥},z) space and
shifted data samples are generated by translating the data samples along the direction of motion in accordance with the distance traveled by the moving object for respective sets of primary phase-encodings.
